(19) United States
(12) Patent Application Publication
(10) Pub. No.: US 2026/0250878 A1
(43) Pub. Date: Aug. 27, 2026

(54) EPITAXIAL GROWTH APPARATUS

(71) Applicant: SK SILTRON CO., LTD., Gyeongsangbuk-do (KR)

(72) Inventors: Seung Jin PARK, Gyeongsangbuk-do (KR); Ji Won Song, Gyeongsangbuk-do (KR); Seung Chul Back, Gyeongsangbuk-do (KR)

(21) Appl. No.: 19/547,855

(22) Filed: Feb. 24, 2026

(30) Foreign Application Priority Data
Feb. 26, 2025 (KR) 10-2025-0025135
Feb. 10, 2026 (KR) 10-2026-0026655

(51) Int. Cl. C30B 25/16; C30B 25/12

(52) U.S. Cl. CPC C30B 25/16; C30B 25/12

(57) ABSTRACT

Disclosed is an epitaxial growth apparatus capable of analyzing thermal distribution resulting from temperature differences in an epitaxial layer deposited on a wafer and varying the position of a reflector based thereon to control the amount of heat supplied to the wafer, thereby depositing an epitaxial layer having a uniform thickness on the surface of the wafer.

### CROSS REFERENCE TO RELATED APPLICATION

This application claims priority under 35 U.S.C. § 119 to Korean Patent Application Nos. 10-2025-0025135, filed Feb. 26, 2025 and 10-2026-0026655, filed Feb. 10, 2026, which is hereby incorporated in its entirety by references as if fully set forth herein.

### TECHNICAL FIELD

Embodiments relate to an epitaxial growth apparatus, and more particularly to an epitaxial growth apparatus capable of measuring changes in the thickness of an epitaxial layer deposited on a wafer, varying the position of a reflector based thereon, and controlling the amount of heat supplied to the wafer.

### BACKGROUND

A wafer is produced through a slicing process of thinly cutting a single-crystal silicon ingot in the form of a wafer, a lapping process of improving flatness of the wafer while polishing the wafer to a desired thickness, an etching process of removing wafer damage, a polishing process of performing mirror finishing and planarization of the wafer, and a cleaning process of removing contaminants from the surface of the wafer.

An epitaxial wafer is produced by forming a thin epitaxial layer on a polished wafer using chemical vapor deposition in a chamber heated to a temperature of 1000° C. or higher. The growth of the epitaxial layer is closely related to temperature. Higher growth temperatures result in faster epitaxial layer growth, whereas lower growth temperatures cause slower epitaxial layer growth. Therefore, when growing an epitaxial layer on a wafer, heat must be uniformly provided across the entire surface of the wafer.

Since the growth rate of an epitaxial layer grown on a silicon wafer is affected by temperature, controlling the temperature distribution across the silicon wafer in a diameter direction is crucial to improve the thickness uniformity of the epitaxial layer. In order to improve the thickness uniformity of the epitaxial layer, deviation in the temperature distribution across the wafer in the diameter direction must be small. To this end, a vapor deposition apparatus may include a reflector configured to provide uniform temperature to a wafer located in a reactor.

As shown in FIG. 1, an epitaxial growth apparatus 100 disclosed in Korean Patent Application Publication No. 10-2019-0047912 may include a reflector 110, a susceptor 120, and a susceptor support 130. A wafer W is mounted on an upper surface of the susceptor 120 with a major surface thereof facing upward. The wafer W may be horizontally disposed on the upper surface of the susceptor 120.

As shown in FIG. 2, the reflector 110 includes a first reflective member 111, a second reflective member 112, a third reflective member 113, and a body portion 114.

The first reflective member 111 extends from a lower part of the body portion 114 into the reflector 110, and is disposed parallel to the wafer W. The first reflective member 111 has a shape protruding from the lower part to a central part of the body portion 114. The second reflective member 112 extends from the lower part of the body portion 114, and is formed inclined in a direction toward the center of the wafer W. The second reflective member 112 has a circular horizontal section that tapers downward toward the center thereof. The third reflective member 113 extends from the second reflective member 112 in a vertical direction.

The conventional reflector 110 has a complex and fixed structure, presenting the problem that it is difficult to adjust the heat supply amount according to the thickness of an epitaxial layer deposited on the surface of the wafer.

### SUMMARY

Embodiments solve the above problems.

Embodiments provide an epitaxial growth apparatus capable of improving the uniformity of the thickness of an epitaxial layer of an epitaxial wafer.

Embodiments provide an epitaxial growth apparatus capable of controlling the amount of heat supplied to a wafer by adjusting the distance between the wafer and a reflector.

An epitaxial growth apparatus according to an embodiment may include a chamber in which deposition gas flows, a susceptor provided in the chamber, the susceptor having an upper surface on which a wafer is seated, a heater disposed above the susceptor, the heater being configured to supply heat to grow an epitaxial layer on the surface of the wafer, a reflector disposed between the heater and the susceptor, the reflector being movable or shape deformable, a measurement unit configured to obtain temperature data of the epitaxial layer deposited on the surface of the wafer, a controller configured to calculate an amount of movement or shape deformation of the reflector to be required based on the temperature data provided from the measurement unit and to control the position or shape of the reflector, and a display unit configured to display information about the amount of movement or shape deformation of the reflector calculated by the controller.

In the epitaxial growth apparatus according to the embodiment, the controller may analyze thermal distribution of the surface of the wafer using the temperature data of the epitaxial layer and calculate the required amount of movement or shape deformation of the reflector.

In the epitaxial growth apparatus according to the embodiment, the controller may output a control signal for reducing temperature deviation of the surface of the wafer by controlling light incident onto a middle part of the wafer in a radial direction of the wafer.

In the epitaxial growth apparatus according to the embodiment, the measuring unit may measure at least one of the thickness profile of the epitaxial layer, roughness of the epitaxial layer, haze of the epitaxial layer, resistivity of the epitaxial layer, and flatness of the epitaxial layer.

In the epitaxial growth apparatus according to the embodiment, the controller may analyze the thermal distribution of the surface of the wafer using thickness data of the epitaxial layer and calculate the required amount of movement or shape deformation of the reflector.

In the epitaxial growth apparatus according to the embodiment, the reflector may have a diameter less than the diameter of the heater.

In the epitaxial growth apparatus according to the embodiment, the reflector may be formed in a doughnut shape parallel to the wafer.

In the epitaxial growth apparatus according to the embodiment, a profile data of the epitaxial layer which is generated may be based on a value measured at a radial distance of 100 mm from the center of the wafer under the condition that the reflector has a radius between 130 mm and 145 mm.

In the epitaxial growth apparatus according to the embodiment, the reflector may be disposed at any one of positions spaced apart from the wafer by 45 mm, 60 mm, 75 mm, and 105 mm.

In the epitaxial growth apparatus according to the embodiment, the controller may control the reflector to be located away from the wafer by a first distance if the epitaxial layer is thinner on an inner side and thicker on an outer side in a radial direction of the wafer, and control the reflector to be located away from the wafer by a second distance larger than the first distance if the epitaxial layer is thicker on the inner side and thinner on the outer side.

An epitaxial growth apparatus according to an embodiment may include a chamber in which deposition gas flows; a susceptor provided in the chamber, the susceptor having an upper surface on which a wafer is seated; a heater disposed above the susceptor, the heater being configured to supply heat to grow an epitaxial layer on a surface of the wafer; and a reflector disposed between the heater and the susceptor and having a doughnut shape.

### BRIEF DESCRIPTION OF THE DRAWINGS

Arrangements and embodiments may be described in detail with reference to the following drawings in which like reference numerals refer to like elements and wherein:

FIG. 1 is a sectional view of a conventional epitaxial growth apparatus;

FIG. 2 is a perspective view of a reflector illustrated in FIG. 1;

FIG. 3 is a schematic side sectional view of an upper part of an epitaxial growth apparatus according to an embodiment;

FIGS. 4A and 4B are, respectively, a plan view and a side sectional view showing a reflector applied to the embodiment;

FIG. 5 is an illustrative view showing the position of a wafer at which measurement is performed and the size of the reflector in the epitaxial growth apparatus according to the embodiment;

FIGS. 6A to 6D are illustrative views showing the states in which the reflector is moved in a vertical direction;

FIG. 7 is a graph showing the intra-wafer variation range according to the width of the reflector applied to the embodiment;

FIG. 8 is a graph showing the intra-wafer light intensity drop position according to the position of the reflector applied to the embodiment;

FIG. 9 is a graph showing the intra-wafer temperature distribution in the prior art and the embodiment;

FIG. 10 is a graph showing the epitaxial layer thickness profile according to the height of the reflector in the epitaxial growth apparatus according to the embodiment; and

FIG. 11 is an illustrative view showing an epitaxial growth apparatus according to another embodiment.

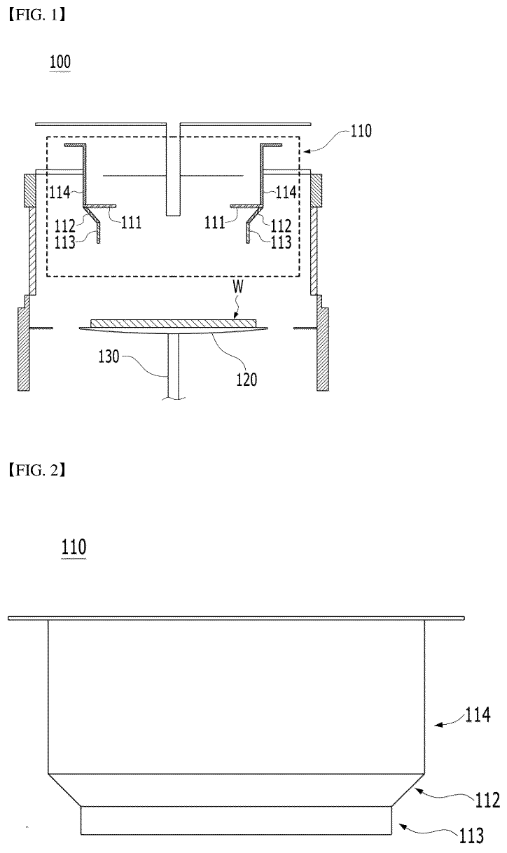

### DESCRIPTION OF SPECIFIC EMBODIMENTS

Specific structural or functional descriptions of embodiments disclosed in this specification are given only for illustrating the embodiments. The embodiments of the present disclosure may be realized in various forms, and should not be interpreted to be limited to the embodiments disclosed in this specification.

Since the embodiments may be variously modified and may have various forms, specific embodiments will be shown in the drawings and will be described in detail in this specification. However, the embodiments are not limited to such specific embodiments, and it should be understood that the embodiments include all alterations, equivalents, and substitutes that fall within the idea and technical scope of the present disclosure.

It will be understood that, although the terms “first”, “second”, etc. may be used herein to describe various elements, corresponding elements should not be understood to be limited by these terms, which are used only to distinguish one element from another. For example, within the scope defined by the present disclosure, a first element may be referred to as a second element, and similarly, a second element may be referred to as a first element.

It will be understood that, when a component is referred to as being “connected to” or “coupled to” another component, it may be directly connected to or coupled to the other component, or intervening components may be present. In contrast, when a component is referred to as being “directly connected to” or “directly coupled to” another component, there are no intervening components present. Other terms that describe the relationship between components, such as “between” and “directly between” or “adjacent to” and “directly adjacent to”, must be interpreted in the same manner.

The terms used in this specification are provided only to explain specific embodiments, but are not intended to restrict the present disclosure. A singular representation may include a plural representation unless it represents a definitely different meaning from the context. It will be further understood that the terms “comprises”, “has” and the like, when used in this specification, specify the presence of stated features, numbers, steps, operations, elements, components or combinations thereof, but do not preclude the presence or addition of one or more other features, numbers, steps, operations, elements, components, or combinations thereof.

Unless otherwise defined, all terms, including technical and scientific terms, used in this specification have the same meanings as those commonly understood by a person having ordinary skill in the art to which the present disclosure pertains. It will be further understood that terms, such as those defined in commonly used dictionaries, should be interpreted as having meanings consistent with their meanings in the context of the relevant art and the present disclosure, and are not to be interpreted in an idealized or overly formal sense unless expressly so defined herein.

Meanwhile, in the case in which a certain embodiment is differently realized, a function or operation specified in a specific block may be performed differently from the sequence specified in a flowchart. For example, two continuous blocks may be substantially simultaneously performed, or the blocks may be performed in reverse order depending on related functions or operations.

Hereinafter, an epitaxial growth apparatus according to an embodiment will be described with reference to the accompanying drawings.

FIG. 3 is a schematic side sectional view of an upper part of an epitaxial growth apparatus according to an embodiment.

The epitaxial growth apparatus 200 according to the embodiment includes a chamber 210, a susceptor 220, a heater 230, a reflector 240, a measurement unit 250, a controller 260, and a display unit 270.

The chamber 210 forms a space through which deposition gas for formation of an epitaxial layer on a wafer 280 flows. A gas inlet and a gas outlet may be provided on both sides of the chamber.

The susceptor 220 is provided in the chamber 210, has an upper surface on which the wafer 280 is seated, and is rotatably installed. Although not shown, a liner (not shown) configured to guide the flow of raw material gas while having a preheating function, may be provided around the susceptor.

The heater 230 is disposed above the susceptor 220 so as to be spaced apart therefrom, is installed along the circumference of the chamber 210, and supplies heat necessary to grow the epitaxial layer on the surface of the wafer 280. The heater 230 may include halogen lamps, but the present disclosure is not limited thereto.

The reflector 240 is disposed between the heater 230 and the susceptor 220 so as to be movable in a vertical direction, i.e. an upward-downward direction. The reflector may reflect a part of the light emitted from the heater 230 to prevent concentration of the light on a radial middle part of the wafer 280 placed on the susceptor 220.

The measurement unit 250 obtains profile data of the epitaxial layer deposited on the surface of the wafer 280. This embodiment exemplifies two measurement units disposed in the chamber 210 so as to face each other. Alternatively, a single measurement unit may be provided since the susceptor 220 is rotatable, or a plurality of measurement units may be disposed to obtain various profile data.

The controller 260 calculates the amount of movement or shape deformation of the reflector 240 to be required based on the profile data provided from the measurement unit 250 and controls the position of shape of the reflector accordingly. The movement of the reflector 240 may include the movement of the reflector 240 in the vertical direction or a horizontal direction. In addition, the shape deformation of the reflector 240 may include changes in the width or the diameter of the reflector 240. Data exchange between the controller 260 and the measurement unit 250 may be performed wirelessly or via wired connections. The controller 260 may be implemented by a computer.

The display unit 270 displays information about the required amount of movement or shape deformation of the reflector 240 calculated by the controller 260. In this embodiment, the movement amount information is visually displayed through a monitor, but the movement amount information may also be presented vocally. In addition, the display unit 270 may be installed outside the chamber 210 rather than being a monitor connected to a computer.

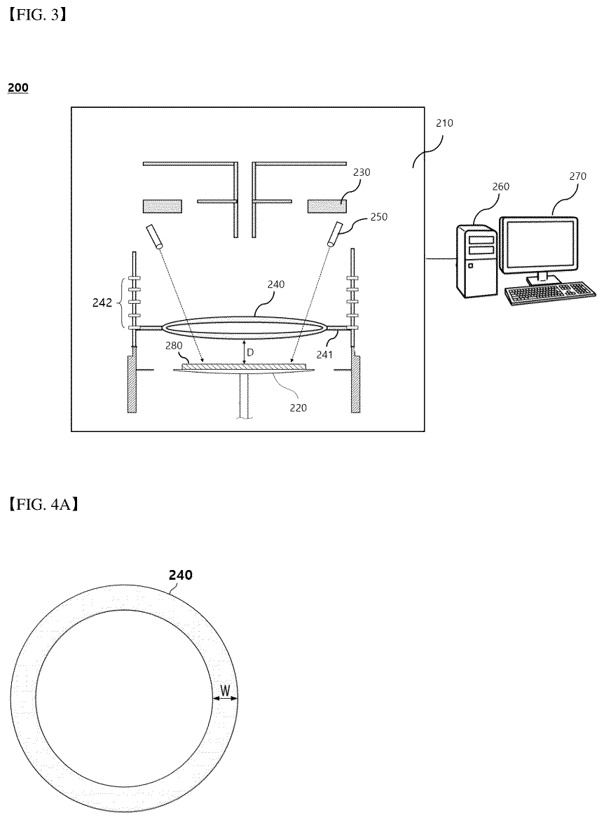

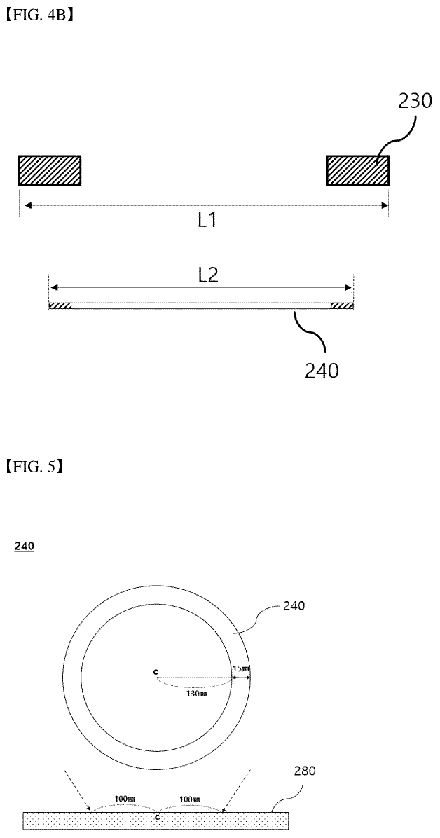

FIGS. 4A and 4B are, respectively, a plan view and a side sectional view showing a reflector 240 applied to the embodiment.

The reflector 240 may have a doughnut shape. The reflector 240 may be mounted by being hung from a peripheral structure so as to be parallel to the susceptor 220 and the wafer 280 by separate wires, but the present disclosure is not limited thereto. The width of the reflector 240 may be 10 mm to 20 mm, and in this embodiment, the reflector has a width of 15 mm.

The diameter L2 of the reflector 240 is less than the diameter L1 of the heater 230.

The radial width W of the reflector 240 and the installation position of the reflector 240 may be set differently depending on the in-plane light intensity distribution of the susceptor 220 or the wafer 280.

After depositing an epitaxial layer on the wafer 280 for a predetermined time, the controller 260 controls the measurement unit 250 to obtain profile data of the epitaxial layer deposited on the wafer.

As shown in FIG. 5, the measurement unit 250 generates profile data based on the value measured at a radial distance of 100 mm from the center of the wafer 280. At this time, the reflector 240 has a width of 15 mm at a radius between 130 mm and 145 mm.

The profile data measured by the measurement unit 250 is temperature data of the epitaxial layer.

The controller 260 receives the temperature profile data from the measurement unit 250. The controller 260 analyzes thermal distribution on the surface of the wafer using, for example, the temperature data of the epitaxial layer among various profile data and calculates the required amount of movement or shape deformation of the reflector 240.

This is one embodiment. After epitaxial growth is complete, the thickness, roughness, haze, resistivity, and flatness of the epitaxial layer may be measured. Based thereon, the controller may calculate the required amount of movement and shape deformation of the reflector and modify the position of the reflector.

The controller 260 controls the reflector to be located away from the wafer by a first distance if the epitaxial layer is thinner on an inner side and thicker on an outer side in a radial direction of the wafer, and controls the reflector to be located away from the wafer by a second distance larger than the first distance if the epitaxial layer is thicker on the inner side and thinner on the outer side. For example, the controller 260 calculates the amount of movement of the reflector 240 such that, if the epitaxial layer is thinner on the inner side and thicker on the outer side based on a wafer radius of 100 mm, the reflector is located 45 mm to 60 mm away from the wafer 280. Subsequently, the epitaxial layer is deposited on the wafer 280 so as to be thicker on the inner side and thinner on the outer side. In this case, the controller 260 calculates the amount of movement of the reflector 240 such that the reflector is located 60 mm to 105 mm away from the wafer 280.

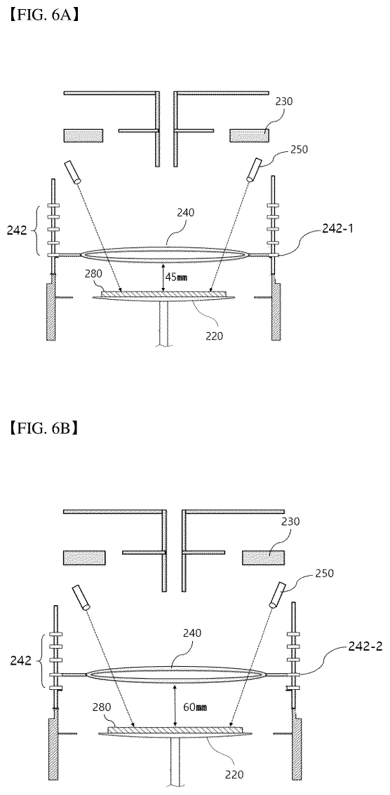

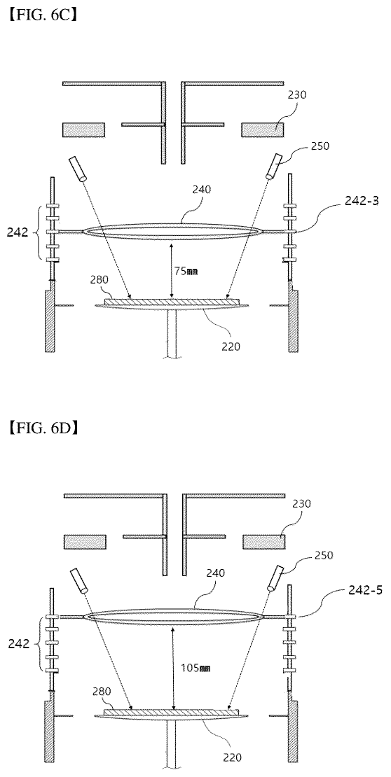

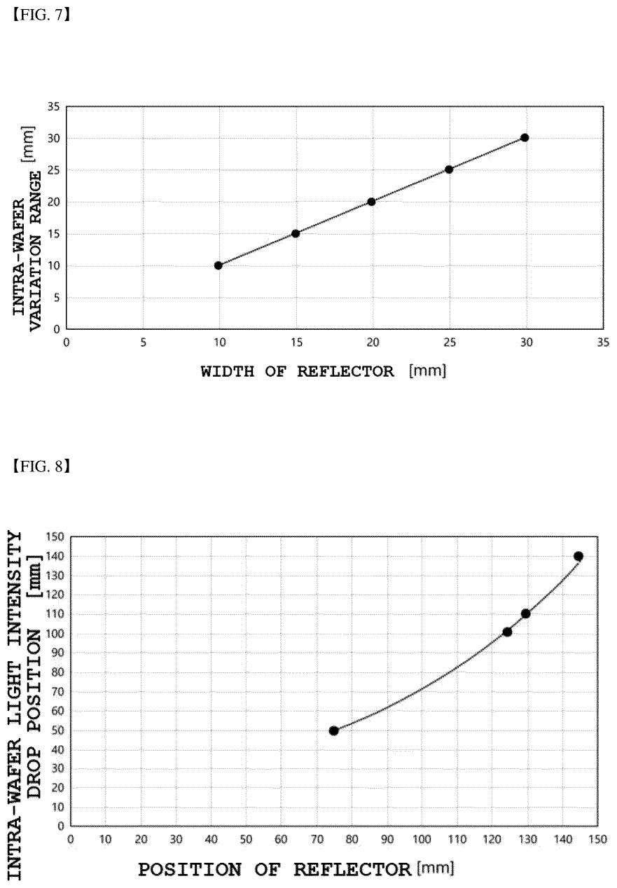

FIGS. 6A to 6D show that the reflector 240 is disposed at various positions based on the data calculated by the controller 260.

FIG. 6A shows the state in which the reflector 240 is fixed to a reflector fixture 242-1 so as to be spaced apart from the wafer 280 by 45 mm. FIG. 6B shows the state in which the reflector 240 is fixed to a reflector fixture 242-2 so as to be spaced apart from the wafer 280 by 60 mm. FIG. 6C shows the state in which the reflector 240 is fixed to a reflector fixture 242-3 so as to be spaced apart from the wafer 280 by 75 mm. FIG. 6D shows the state in which the reflector 240 is fixed to a reflector fixture 242-5 so as to be spaced apart from the wafer 280 by 105 mm. A reflector fixture 242 is shown as being configured such that the respective fixtures 242-1 to 242-5 are disposed at intervals of 15 mm, but this is one embodiment and the present disclosure is not limited thereto.

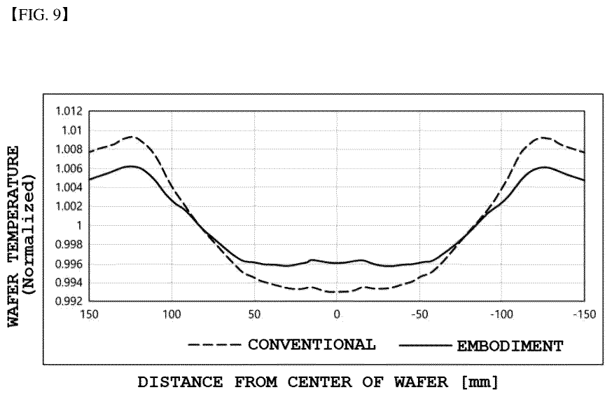

FIG. 7 is a graph showing the intra-wafer variation range according to the width of the reflector applied to the embodiment, and FIG. 8 is a graph showing the intra-wafer light intensity drop position according to the position of the reflector applied to the embodiment.

As shown in FIG. 7, it can be seen that, as the width of the reflector applied to the embodiment increases, the intra-wafer temperature variation range also increases. Therefore, it is desirable to configure the width of the reflector to be equal to the width of the intra-wafer hot spot.

As shown in FIG. 8, as the position of the reflector applied to the embodiment increases in a radial direction, the intra-wafer light intensity drop position also increases in the radial direction. Since the reflector is located farther inward than the heater, it can be seen that the intra-wafer light intensity drop position in the radial direction appears farther inward than the position of the reflector in the radial direction. That is, it is desirable for the position of the reflector in the radial direction to be located at a predetermined distance outward from the intra-wafer hot spot.

FIG. 9 is a graph showing the intra-wafer temperature distribution in the prior art and the embodiment. In the embodiment, the doughnut-shaped reflector with adjustable position is provided between the heater and the wafer, compared to the prior art. Consequently, light concentrated on the radial middle part of the wafer at which temperatures are relatively high may be blocked or dispersed by controlling the distance between the reflector and the heater based on the measured thickness of the currently deposited epitaxial layer, and therefore it is possible to reduce the intra-wafer temperature variation and to achieve a more uniform thickness of the epitaxial layer deposited across the entire wafer.

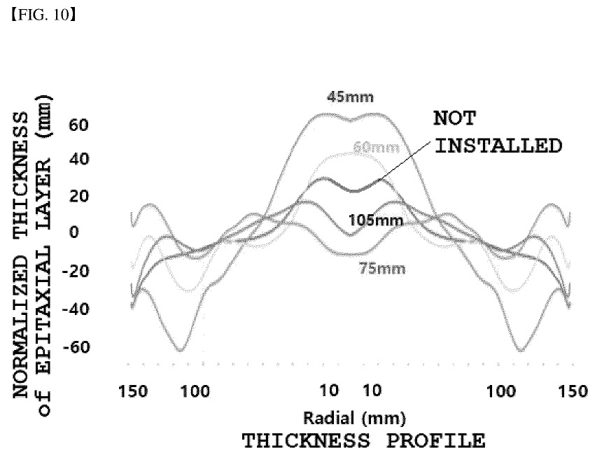

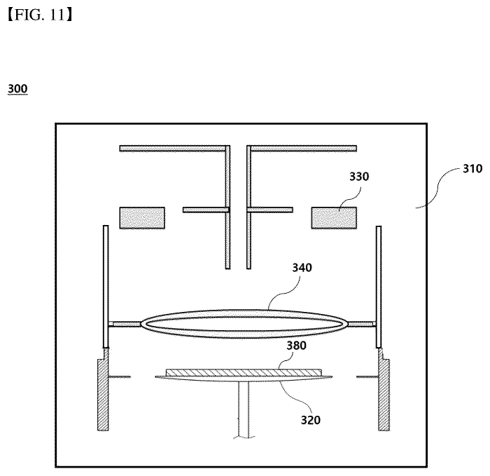

FIG. 10 is a graph showing the epitaxial layer thickness profile according to the height of the reflector in the epitaxial growth apparatus according to the embodiment. The horizontal axis indicates the distance from the center to the periphery of the wafer, and the vertical axis indicates the normalized thickness of the epitaxial layer. The difference between the epitaxial layer thickness at each position and the average thickness of the entire epitaxial layer when the position of the reflector is varied from 45 mm to 105 mm is shown. That is, when the reflector is spaced apart from the surface of the wafer by 45 mm, the difference between the thickness of the epitaxial layer at a distance of approximately 10 mm from the center of the wafer and the average thickness of the entire epitaxial layer is approximately 60 nm. When the reflector is spaced apart from the surface of the wafer by 60 mm, the difference between the thickness of the epitaxial layer at a distance of approximately 10 mm from the center of the wafer and the average thickness of the entire epitaxial layer is approximately 40 nm. When the reflector is spaced apart from the surface of the wafer by 105 mm, the difference between the thickness of the epitaxial layer at a distance of approximately 10 mm from the center of the wafer and the average thickness of the entire epitaxial layer is approximately 20 nm. When the reflector is spaced apart from the surface of the wafer by 75 mm, the difference between the thickness of the epitaxial layer at a distance of approximately 10 mm from the center of the wafer and the average thickness of the entire epitaxial layer is approximately −10 nm.

Meanwhile, when the reflector is spaced apart from the surface of the wafer by 45 mm, the difference between the thickness of the epitaxial layer at a distance of approximately 100 mm from the center of the wafer and the average thickness of the entire epitaxial layer is approximately −60 nm. When the reflector is spaced apart from the surface of the wafer by 60 mm, the difference between the thickness of the epitaxial layer at a distance of approximately 100 mm from the center of the wafer and the average thickness of the entire epitaxial layer is approximately −30 nm. When the reflector is spaced apart from the surface of the wafer by 105 mm, the difference between the thickness of the epitaxial layer at a distance of approximately 100 mm from the center of the wafer and the average thickness of the entire epitaxial layer is approximately −5 nm. When the reflector is spaced apart from the surface of the wafer by 75 mm, the difference between the thickness of the epitaxial layer at a distance of approximately 100 mm from the center of the wafer and the average thickness of the entire epitaxial layer is approximately −10 nm.

FIG. 11 is an illustrative view showing an epitaxial growth apparatus according to another embodiment.

As shown in FIG. 11, the epitaxial growth apparatus 300 according to the other embodiment may include a chamber 310 through which deposition gas flows, a susceptor provided in the chamber 310, the susceptor having an upper surface on which a wafer is seated, a heater disposed above the susceptor, the heater being configured to supply heat necessary to grow an epitaxial layer to the surface of the wafer, and a doughnut-shaped reflector 340 disposed between the heater and the susceptor.

Unlike the embodiment of FIG. 3, the reflector 340 may be fixed in the chamber 310. The description given with reference to FIGS. 4A and 4B applies to the shape and size of the reflector and the relationship between the reflector and the heater.

As is apparent from the above description, the epitaxial growth apparatus according to the embodiment is capable of reducing the intra-wafer temperature variation and thus achieving a more uniform thickness of the epitaxial layer deposited across the entire wafer, thereby improving wafer quality.

Although the present disclosure has been described above with reference to exemplary embodiments, those skilled in the art will understand that the present disclosure can be modified and changed in various ways without departing from the spirit and scope of the disclosure as defined in the appended claims.

What is claimed is:

1. An epitaxial growth apparatus, comprising:
a chamber in which deposition gas flows;
a susceptor provided in the chamber, the susceptor having an upper surface on which a wafer is seated;
a heater disposed above the susceptor, the heater being configured to supply heat to grow an epitaxial layer on a surface of the wafer;
a reflector disposed between the heater and the susceptor, the reflector being movable or shape deformable;
a measurement unit configured to obtain temperature data of the epitaxial layer deposited on the surface of the wafer;
a controller configured to calculate an amount of movement or shape deformation of the reflector to be required based on the temperature data provided from the measurement unit and to control a position or shape of the reflector; and
a display unit configured to display information about the required amount of movement or shape deformation of the reflector calculated by the controller.

2. The epitaxial growth apparatus according to claim 1, wherein the controller analyzes thermal distribution of the surface of the wafer using the temperature data of the epitaxial layer and calculates the required amount of movement or shape deformation of the reflector.

3. The epitaxial growth apparatus according to claim 2, wherein the controller outputs a control signal for reducing temperature deviation of the surface of the wafer by controlling light incident onto a middle part of the wafer in a radial direction of the wafer.

4. The epitaxial growth apparatus according to claim 1, wherein the reflector has a diameter less than a diameter of the heater.

5. The epitaxial growth apparatus according to claim 1, wherein the reflector is formed in a doughnut shape parallel to the wafer.

6. The epitaxial growth apparatus according to claim 5, wherein a profile data of the epitaxial layer which is generated is based on a value measured at a radial distance of 100 mm from a center of the wafer under a condition that the reflector has a radius between 130 mm and 145 mm.

7. The epitaxial growth apparatus according to claim 6, wherein the reflector is disposed at any one of positions spaced apart from the wafer by 45 mm, 60 mm, 75 mm, and 105 mm.

8. The epitaxial growth apparatus according to claim 5, wherein the controller controls the reflector to be located away from the wafer by a first distance if the epitaxial layer is thinner on an inner side and thicker on an outer side in a radial direction of the wafer, and controls the reflector to be located away from the wafer by a second distance larger than the first distance if the epitaxial layer is thicker on the inner side and thinner on the outer side.

9. The epitaxial growth apparatus according to claim 1, wherein the measuring unit measures at least one of a thickness profile of the epitaxial layer, roughness of the epitaxial layer, haze of the epitaxial layer, resistivity of the epitaxial layer, and flatness of the epitaxial layer.

10. An epitaxial growth apparatus, comprising:
a chamber in which deposition gas flows;
a susceptor provided in the chamber, the susceptor having an upper surface on which a wafer is seated;
a heater disposed above the susceptor, the heater being configured to supply heat to grow an epitaxial layer on a surface of the wafer; and
a reflector disposed between the heater and the susceptor and having a doughnut shape.
